(19) United States
(12) Patent Application Publication
(10) Pub. No.: US 2025/0301591 A1
(43) Pub. Date: Sep. 25, 2025

(54) MODULE

(71) Applicant: Hitachi-LG Data Storage, Inc., Tokyo (JP)

(72) Inventor: Naoya MATSUURA, Tokyo (JP)

(21) Appl. No.: 19/050,683

(22) Filed: Feb. 11, 2025

(30) Foreign Application Priority Data
Mar. 25, 2024 (JP) 2024-047465

(51) Int. Cl. H05K 7/14; H05K 5/02; H05K 7/20

(52) U.S. Cl. CPC H05K 7/1427; H05K 5/0217; H05K 7/2039

(57) ABSTRACT

Provide a module that can improve heat dissipation efficiency. The module has a housing and an electronic component mounting board that is housed in the housing and has a semiconductor device and a board on which the semiconductor device is mounted. In the module, a first metal layer formed on an inner surface of a first face part of the housing and the housing side surface of the semiconductor device are in contact. In the module, a stacked part in which the first metal layer and a second metal layer are stacked is formed on at least a part of a second region between an outer edge of a first region including the contact surface between the first metal layer and the housing side surface of the semiconductor device and an outer edge of an inner surface of the housing.

### CROSS-REFERENCE TO RELATED APPLICATION

The present application claims priority from Japanese application JP2024-047465, filed on Mar. 25, 2024, the content of which is hereby incorporated by reference into this application.

### BACKGROUND OF THE INVENTION

### 1. Field of the Invention

The present invention relates to a module.

### 2. Description of the Related Art

Patent document 1 (Japanese Patent Application Laid-Open No. 2023-140028) discloses an electronic device including an SSD (Solid State Drive) module. This conventional electronic device has a board, a DRAM (Dynamic Random Access Memory), an SSD controller, a NAND flash memory, a connector part, a screw fastening part, and a heat dissipating rubber. The heat dissipating rubber is positioned to contact the SSD controller and ground wiring of a motherboard. As a result, the electronic device dissipates heat generated in the SSD controller to the motherboard via the heat dissipating rubber.

Furthermore, the electronic device improves resistance to vibration and shock by arranging the heat dissipating rubber to cover the SSD controller.

An external SSD module has a configuration in which a mounting board on which electronic components (semiconductor devices (semiconductor chips)) such as a flash memory and a controller are mounted is housed in a housing. In the module with such a configuration, there is a need to improve heat dissipation efficiency to efficiently dissipate heat generated by the electronic components to the outside (external environment) via the housing. The conventional technology of Patent Document 1 dissipates heat to the motherboard via the heat dissipating rubber. However, the conventional technology of Patent Document 1 does not consider heat dissipation efficiency in the configuration where the mounting board is housed in the housing.

### SUMMARY OF THE INVENTION

The present invention has been made to solve the above problems. That is, one of the purposes of the present invention is to provide a module that can improve heat dissipation efficiency.

To solve the above problem, the module of the present invention comprises:
a housing with a first face part and a second face part that are opposite each other; and
an electronic component mounting board that is housed in the housing and that has a semiconductor device and a board on which the semiconductor device is mounted.

The first metal layer formed on at least a part of an inner surface of at least one of the first face part and the second face part of the housing and a surface on a housing side of the semiconductor device are in direct or indirect contact; and
a stacked part in which the first metal layer and the second metal layer are stacked is formed on at least a part of a second region between an outer edge of a first region including a contact surface between the first metal layer and the surface on the housing side of the semiconductor device and the outer edge of the inner surface of the housing.

According to the present invention, heat dissipation efficiency can be improved. It should be noted that the effects described herein are not necessarily limited to any of the effects described in the present invention.

### BRIEF DESCRIPTION OF THE DRAWINGS

FIG. 1 is a perspective view showing the appearance of a module.

FIG. 2 is a perspective view showing an electronic component boards group.

FIG. 3 shows a cross-sectional view along line III-III′ of FIG. 1.

FIG. 4 shows a cross-sectional view along line IV-IV′ of FIG. 1.

FIG. 5 is a plan view along line V-V′ of FIG. 3.

FIG. 6 is a plan view along line VI-VI′ of FIG. 3.

FIG. 7 shows schematically the cross-sectional configuration of the modules in Comparative Example 1, Comparative Example 2, and Embodiment Example

FIG. 8A illustrates the effect and function of the module according to the first embodiment.

FIG. 8B illustrates the effect and function of the module according to the first embodiment.

FIG. 9 shows the temperature characteristics of semiconductor chips in the embodiment example module and the module of Comparative Example 2.

FIG. 10 shows the temperature characteristics and data transfer rate of the embodiment example module and the module of Comparative Example 3.

FIG. 11 shows a cross-sectional view along line III-III′ of FIG. 1.

FIG. 12 shows a cross-sectional view along line IV-IV′ of FIG. 1.

FIG. 13 is a plan view along line XIII-XIII′ of FIG. 11.

FIG. 14 is a plan view along line XIV-XIV′ of FIG. 11.

FIG. 15 shows a cross-sectional view along line III-III′ of FIG. 1.

FIG. 16 shows a cross-sectional view along line III-III′ of FIG. 1.

### DETAILED DESCRIPTION OF THE PREFERRED EMBODIMENT

Each embodiment of the present invention will be described below with reference to the drawings. In all figures of the embodiments, identical or corresponding parts may be marked with the same symbol.

### First Embodiment

### Configuration

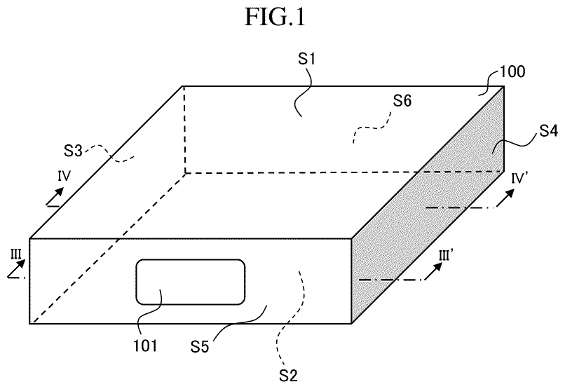

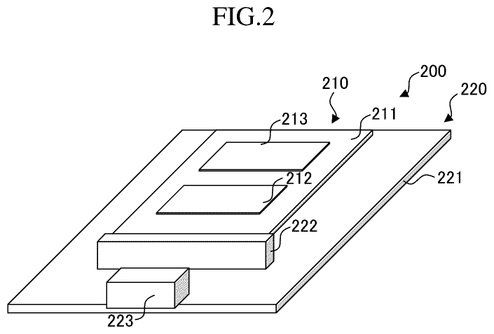

The following is a description of a module according to the first embodiment of the present invention. FIG. 1 is a diagram showing the appearance of the module. The module according to the first embodiment is an external SSD module. The module includes a housing 100, an electronic component mounting boards group 200 (see FIG. 2.)

The housing 100 has first and second face parts S1 and S2 facing each other in the vertical direction, third and fourth face parts S3 and S4 facing each other in the width direction, and fifth and sixth face parts S5 and S6 facing each other in the front-back direction. The housing 100 has an abbreviated rectangular housing space surrounded by the inner surfaces of the first to sixth face parts S1 to S6. The electronic component mounting boards group 200 shown in FIG. 2 is housed in this housing space.

The fifth face part S5 of the housing 100 has an opening 101 that connects the inside to the outside. A USB port 223 (see FIG. 2.) for connecting to an external device (such as a PC (personal computer)) through opening 101 is exposed to the outside.

As shown in FIG. 2, the electronic component mounting boards group 200 includes a first mounting board 210 and a second mounting board 220. The first mounting board 210 includes a first board 211 and electronic components including a controller 212, and a NAND flash memory 213 (hereinafter sometimes referred to as a “flash memory 213”). The electronic components and wiring not shown are mounted on the first board 211. It should be noted that the controller 212 and the NAND flash memory 213 may be referred to as a “semiconductor chip” or a “semiconductor device”.

The controller 212 is a control device for controlling the reading and writing of data to the flash memory 213. The flash memory 213 is a nonvolatile storage element capable of reading, writing, and erasing data.

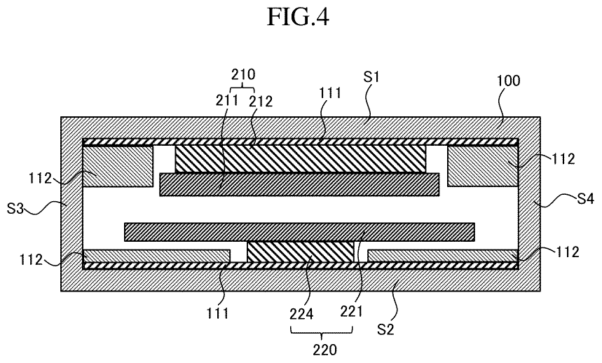

The second mounting board 220 includes a second board 221 and electronic components including a connector 222, a USB port 223 and a bridge-IC (Bridge-IC) 224 (see FIG. 4.).

The electronic components and wiring (not shown) are mounted on the second board 221. It should be noted that the bridge IC 224 may also be referred to as a “semiconductor chip” or a “semiconductor device” for convenience of description.

The connector 222 is a connector for connecting the first mounting board 210 and the second mounting board 220. The USB port 223 is an interface for connecting the module to an external device (such as a PC). The bridge IC 224 is an IC for streamlining data transfer between the flash memory 213 and the controller 212.

It should be noted that the examples of the electronic components mounted on the first and second boards 211 and 221 are examples and are not limited to these, and the electronic components are mounted on the boards according to the functions provided by the module.

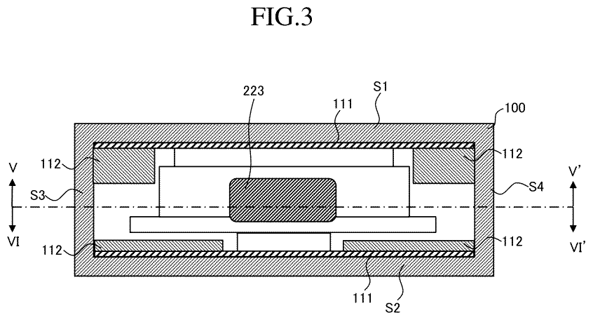

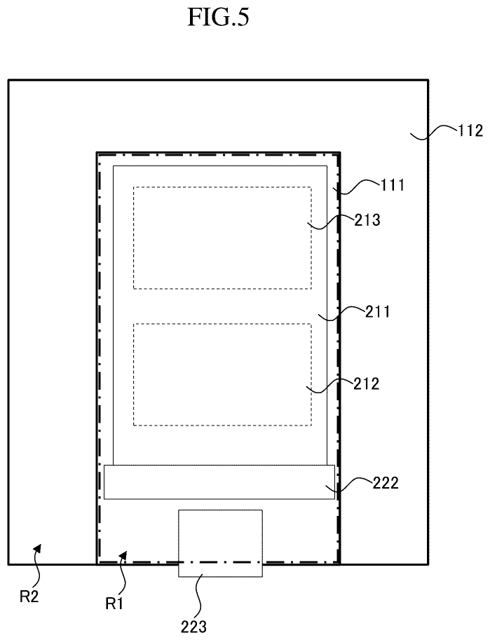

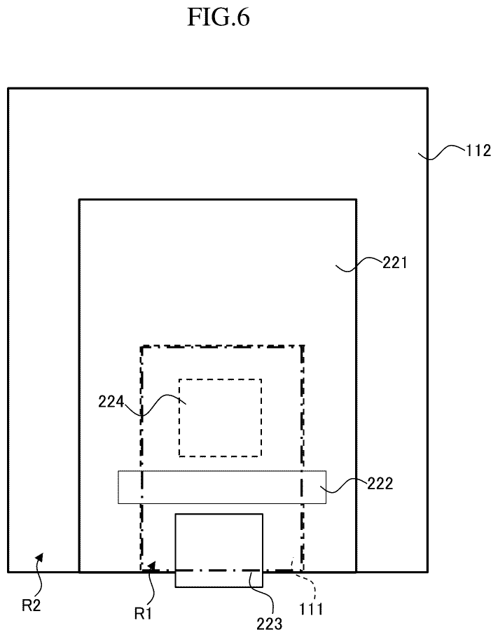

FIG. 3 is a cross-sectional view along line III-III′ of FIG. 1. FIG. 4 is a cross-sectional view along line IV-IV′ of FIG. 1. FIG. 5 is a plan view along line V-V′ of FIG. 3. FIG. 6 is a plan view along line VI-VI′ of FIG. 3.

As shown in FIGS. 3 and 4, the first metal layer 111 is stacked on the inner surface of the first face part S1. The first metal layer 111 is laminated with a first mounting board 210 and a second metal layer 112. The first mounting board 210 is stacked on the first metal layer 111 so that the face on the housing 100 side of the semiconductor chips (the controller 212 and the flash memory 213) are in contact with the first metal layer 111.

As shown in FIG. 5, when viewed in plan in the direction indicated by the arrow on the line V-V′ in FIG. 3, the inner surface of the first face part S1 is divided into a rectangular first region R1 (the region enclosed by the single-dotted line) and a rectangular second region R2 between the outer edge of the first region R1 and the outer edge of the inner surface of the first face part S1. The first region R1 includes at least the contact surfaces of the semiconductor chips (the controller 212 and the flash memory 213) on the housing 100 side and the first metal layer 111. In this example, the shape of the first region R1 is rectangular, but may be any other shape. In the second region R2, a stacked part of the first metal layer 111 and the second metal layer 112 is formed. This stacked part consists of a part of the first metal layer 111 stacked on the inner surface of the first face part S1 (all of the inner surface) and the second metal layer 112 stacked on a part of the first metal layer 111. In this example, the stacked part is formed over (all of) all of the second region R2, but the stacked part may be formed on a part of the second region R2. In this example, the side surfaces of the stacked part is in contact with the inner surfaces of the side face parts (the third face part S3, the fourth face part S4, the fifth face part S5, and the sixth face part S6) of the housing100, but the side surfaces of the stacked part may not be in contact with the side face part (the third face part S3, the fourth face part S4, the fifth face part S5, and the sixth face part S6) of the housing 100. From the viewpoint of heat dissipation efficiency, it is preferable that the side surface of the stacked part is in contact with the side face parts (the third face part S3, the fourth face part S4, the fifth face part S5, and the sixth face part S6) of the housing 100 and from the viewpoint of ease of design and assembly, it is preferable that the side surface of the stacked part does not contact the side face parts (the third face part S3, the fourth face part S4, the fifth face part S5, and the sixth face part S6) of the housing 100. From the viewpoint of ease of assembly, it is preferable that the inner peripheral edge of the stacked part and the outer peripheral edge of the semiconductor chip facing the inner peripheral edge of the stacked part are separated by a predetermined width. This predetermined width should be 2 mm or less from the viewpoint of improving heat dissipation efficiency.

Each of the first metal layer 111 and the second metal layer 112 is composed of a metal such as copper, iron, etc.

The first metal layer 111 and the second metal layer 112 may be composed of the same metal or of different metals. The thermal conductivity of the metal (the first metal) comprising the first metal layer 111 should be greater than or equal to the thermal conductivity of the metal (the second metal) comprising the second metal layer 112 from the viewpoint of obtaining better heat dissipation efficiency.

The metal comprising the first metal layer 111 is, for example, copper or aluminum.

The material comprising the second metal layer 112 is preferably a metal having a thermal conductivity greater than or equal to the thermal conductivity of iron. The metal comprising the second metal layer 112 is, for example, aluminum, copper, iron, etc.

In this example, the first metal layer 111 is a copper foil sheet and the second metal layer 112 is an aluminum plate. The thickness of the first metal layer 111 should be 0.1 mm or less from the viewpoint of reducing the thickness of the module.

The thickness of the second metal layer 112 should be thicker than that of the first metal layer 111 from the viewpoint that the heat dissipation efficiency can be further improved by increasing the heat dissipation path. From the viewpoint of increasing the number of heat dissipation paths and thereby improving heat dissipation efficiency, the thickness of second metal layer 112 is preferably 0.5 mm or more and 3 mm or less, and more preferably 1 mm or more and 3 mm or less.

As shown in FIGS. 3 and 4, the first metal layer 111 is stacked on the inner surface of the second face part S2. The second mounting board 220 and the second metal layer 112 are stacked on the first metal layer 111. The second mounting board 220 is provided so that the surface on the housing 100 side of the semiconductor chip (the bridge IC 224) is in contact with the first metal layer 111.

As shown in FIG. 6, when viewed in plan in the direction indicated by the arrow on line VI-VI′ in FIG. 3, the inner surface of the second face part S2 is divided into a rectangular first region R1 (surrounded by a single dotted line) and a second region R2 between the outer edge of the first region R1 and the outer edge of the inner surface of the second face part S2. The first region R1 includes at least the contact surface between the first face on the housing 100 side of the semiconductor chip (bridge IC 224) and the first metal layer 111. In this example, the shape of the first region R1 is rectangular, but may be any other shape. In the second region R2, a stacked part of the first metal layer 111 and the second metal layer 112 is formed. This stacked part consists of a part of the first metal layer 111 stacked on the inner surface of the second face part S2 (all of the inner surface) and the second metal layer 112 stacked on a part of the first metal layer 111. In this example, the stacked part is formed over all (all of) the second region R2, but the stacked part may be formed in a part of the second region R2. From the viewpoint of heat dissipation efficiency, it is preferable that the side surface of the stacked part is in contact with the side face parts (the third face part S3, the fourth face part S4, the fifth face part S5, and the sixth face part S6) of the housing 100 and from the viewpoint of ease of design and assembly, it is preferable that the side surface of the stacked part does not contact the side face parts (the third face part S3, the fourth face part S4, the fifth face part S5, and the sixth face part S6) of the housing 100. From the viewpoint of ease of assembly, it is preferable that the inner peripheral edge of the stacked part and the outer peripheral edge of the semiconductor chip facing the inner peripheral edge of the stacked part are separated by a predetermined width. This predetermined width should be 2 mm or less from the viewpoint of improving heat dissipation efficiency.

On the inner surface of the first face part S1, the module has a stacked part of the first metal layer 111 and the second metal layer 112 in the second region R2 outside the first region R1 that includes the contact surface between the housing 100 side surface of the semiconductor chip and the first metal layer 111. Further, the module has a stacked part of the first metal layer 111 and the second metal layer 112 in the second region R2 outside the first region R1 that includes the contact surface between the housing 100 side surface of the semiconductor chip and the first metal layer 111 on the inner surface of the second face part S2. The module can improve the heat dissipation efficiency by having the stacked part formed in the second region R2, so the heat generated by the semiconductor chip can be efficiently dissipated outside without increasing the thickness of the module. The details of this effect are described below.

### Detail of Functions and Effects

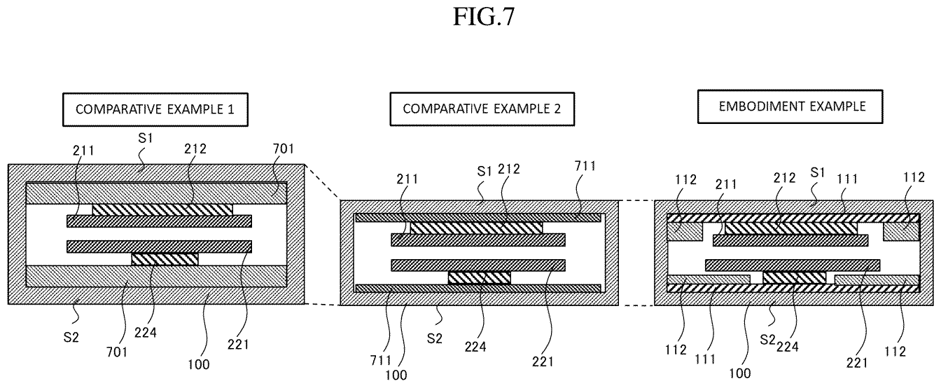

The details of the functions and the effects of the present invention will be explained in comparison with conventional configurations. FIG. 7 schematically shows the cross-sectional configuration of the module of Comparative Example 1, the module of Comparative Example 2, and the module (the embodiment example module) of Embodiment Example. In the module of Comparative Example 1, the aluminum plate 701 is stacked on the inner surface of the first face part S1 of the housing 100 and the aluminum plate 701 is stacked on the inner surface of the second face part S2 of the housing 100. In the module of Comparative Example 1, the aluminum plate 701 is in contact with the surface on the housing 100 side of the semiconductor chip. The typical thickness of the aluminum plate 701 is about 1 mm.

In the module of Comparative Example 2, the graphite sheet 711 is stacked on the inner surface of the first face part S1 of the housing 100 and the graphite sheet 711is stacked on the inner surface of the second face part S2. In the module of Comparative Example 2, the graphite sheet 711 is in contact with the housing 100 side surface of the semiconductor chip. The typical thickness of the graphite sheet 711 is 0.05 mm or more and 0.1 mm or less, thinner than the aluminum plate 701.

The embodiment example module is a module corresponding to the first embodiment. In the embodiment example module, the first metal layer (copper foil sheet) 111 is stacked on the inner surface of the first face part S1 of the housing 100 and the first metal layer (copper foil sheet) 111 is stacked on the inner surface of the second face part S2 of the housing 100. The typical thickness of the first metal layer (copper foil sheet) 111 is 0.05 mm or more and 0.1 mm or less.

In the embodiment example module, the first metal layer (copper foil sheet) 111 on the inner surface of the first face part S1 is in contact with the surface on the housing 100 side of the semiconductor chip. The embodiment example module has a stacked part of the second metal layer (aluminum plate) 112 and the first metal layer (copper foil sheet) 111 in the second region R2 outside the first region R1 that includes the contact surface between the semiconductor chip and the first metal layer (copper foil sheet) 111.

In the embodiment example module, the first metal layer (copper foil sheet) 111 on the inner surface of the second face part S2 is in contact with the surface on the housing 100 side of the semiconductor chip. The embodiment example module has a stacked part of the second metal layer (aluminum plate) 112 and the first metal layer (copper foil sheet) 111 in the second region R2 outside the first region R1 that includes the contact surface between the semiconductor chip and the first metal layer (copper foil sheet) 111.

The module of Comparative Example 1 has low cost and high heat transfer performance. However, the module of Comparative Example 1 requires the thickness of 701 aluminum plates, which makes the module thicker. The module of Comparative Example 2 can reduce the thickness of the module. However, the module of Comparative Example 2 is more expensive due to the high cost of graphite sheet 711.

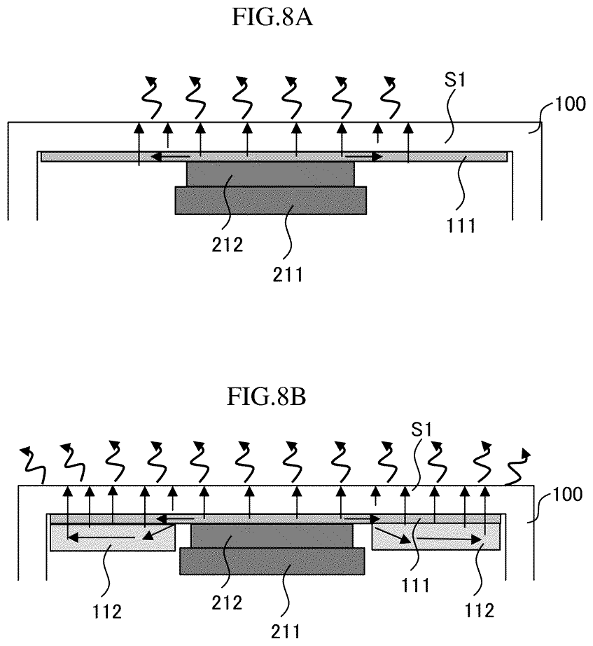

In contrast to these Comparative Examples 1 and 2, the module of the Embodiment Example uses a copper foil sheet as the first metal layer 111 that contacts the semiconductor chip. The copper foil sheet is comparable in thickness to graphite sheets and is inexpensive. However, the thermal conductivity of the copper foil sheet in the plane direction is approximately ¼ or more and ⅓ or less than that of the graphite sheet. Therefore, the heat dissipation efficiency of the copper foil sheet alone may be reduced (may not be sufficient.) In contrast, the embodiment example module has the stacked part in the second region R2. This allows the embodiment example module to increase the heat dissipation path compared to the case with only the copper foil sheet, thus improving heat dissipation efficiency (see FIG. 8A and FIG. 8B below.).

FIGS. 8A and 8B illustrate the function and the effect of the first embodiment of the module. It should be noted that, in FIGS. 8A and 8B, the flow of heat is indicated by arrows. FIG. 8A shows the module of the reference example, and FIG. 8B shows the module according to the first embodiment. It should be noted that the reference example module differs from the embodiment example module only in that the second metal layer (aluminum plate) 112 is omitted.

As shown in FIG. 8A, the first metal layer (copper foil sheet) 111 alone has a small cross-sectional area, making it difficult to transfer heat to the edge of the first face part S1, thus reducing the area of the heat dissipation surface of the housing 100 that allows heat to escape outside. In contrast, as shown in FIG. 8B, by providing the stacked part of the first metal layer (copper foil sheet) 111 and the second metal layer (aluminum plate) 112 in the second region R2, heat can be easily transferred to the edge of the first face part S1, and the area of the heat dissipation surface of the housing 100 where heat escapes to the outside is larger than in the module of the reference example. As a result, the module of the first embodiment can suppress the temperature rise of the semiconductor chip by improving the heat dissipation efficiency of the heat generated in the semiconductor chip compared to the module of the reference example.

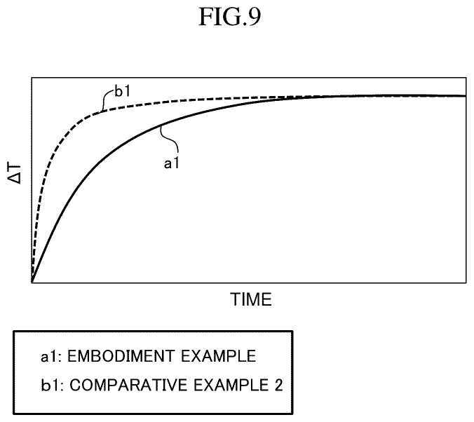

FIG. 9 shows the temperature characteristics of the semiconductor chip of the embodiment example module and the module of Comparative Example 2. In FIG. 9, line al shows the temperature characteristics of the semiconductor chip when the module of Embodiment Example is used, and line b1 shows the temperature characteristics of the semiconductor chip when the module of Comparative Example 2 is used. As shown in lines al and b1, in the module of Comparative Example 2, which uses the graphite sheet with a low heat capacity, the semiconductor chip reaches a high temperature immediately after the start of use. In contrast, the embodiment example module uses the aluminum plate with a larger heat capacity than the graphite sheet, so it takes time for the semiconductor chip to reach a high temperature. Therefore, compared to the module of Comparative Example 2, the embodiment example module can suppress the temperature rise of the semiconductor chip when used for a short time.

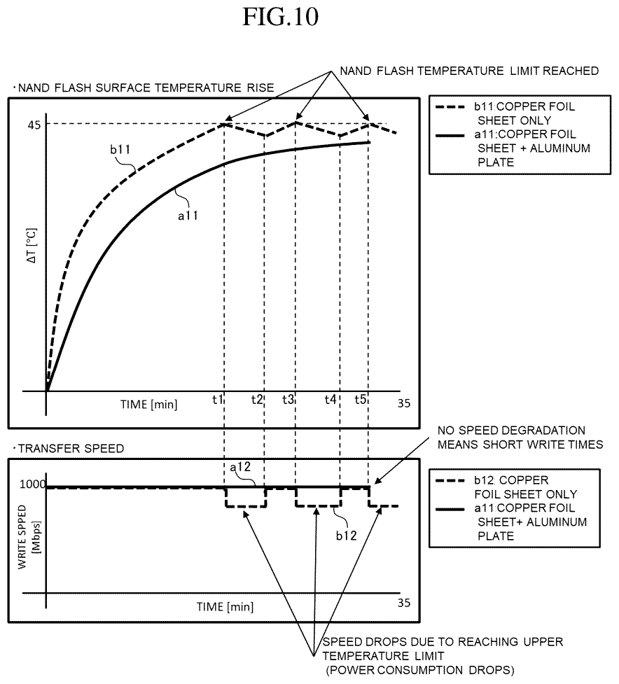

FIG. 10 is a graph showing the temperature characteristics and data transfer rate of the embodiment example module and reference example module. In FIG. 10, line a11 shows the surface temperature change of NAND flash memory 213 when the embodiment example module is used (2 TB of data is written). Line a12 shows the data transfer rate when the embodiment example module is used (2 TB of data is written). Line b11 shows the temperature change of NAND flash memory 213 when the module in the reference example is used (2 TB of data is written). Line b12 shows the data transfer rate when the reference example module is used (2 TB of data is written).

As shown by line b11, in the reference example module, the upper temperature limit (ΔT: 45° C.) of the NAND flash memory 213 is reached at time t1, time t3 and time t5. As shown by line b12, in the reference example module, the speed decreased due to the temperature limit being reached from time t1 to time t2, from time t3 to time t4, and after time t5. In contrast, in the embodiment example module, as shown in lines a11 and a12, the upper temperature limit of the NAND flash memory 213 is not reached and no speed drop occurred. In addition, since the embodiment example module did not experience a speed decrease due to temperature rise, the data write time was reduced compared to the module of the reference example.

### Effect

As explained above, the module according to the first embodiment of the present invention can improve heat dissipation efficiency without increasing the thickness of the module by having the stacked part in the second region R2 outside the first region R1 that includes the contact surface between the housing 100 side surface of the semiconductor chip and the first metal layer 111 on the inner surface of the housing 100. The module according to the first embodiment can suppress a decrease in data transfer rate due to temperature rise.

### Second Embodiment

The module (SSD module) according to the second embodiment of the present invention will be described. The module according to the second embodiment differs from the module according to the first embodiment in the configuration and the arrangement of the first metal layer 111 and the second metal layer 112.

The following explanation focuses on these differences.

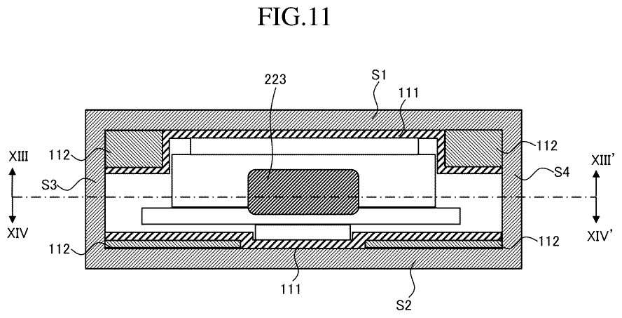

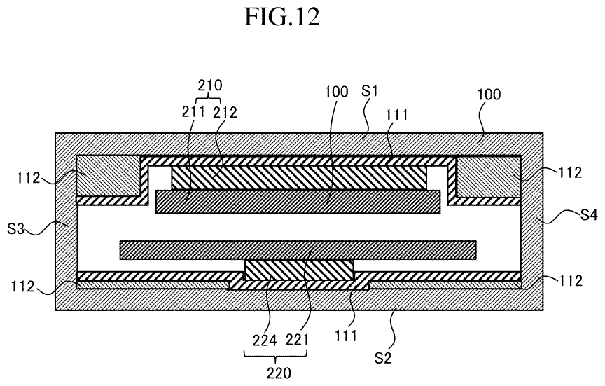

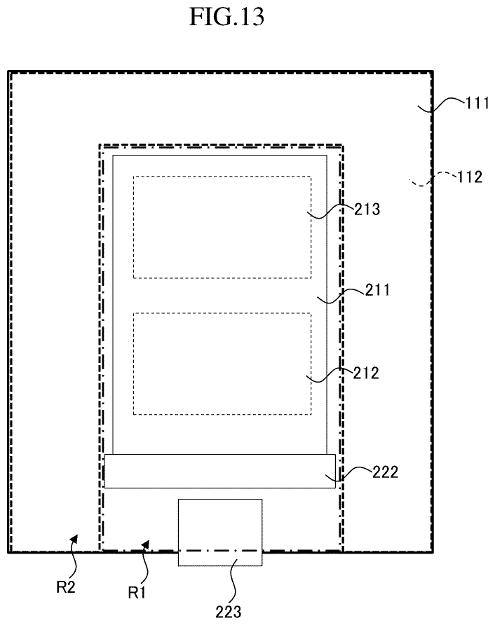

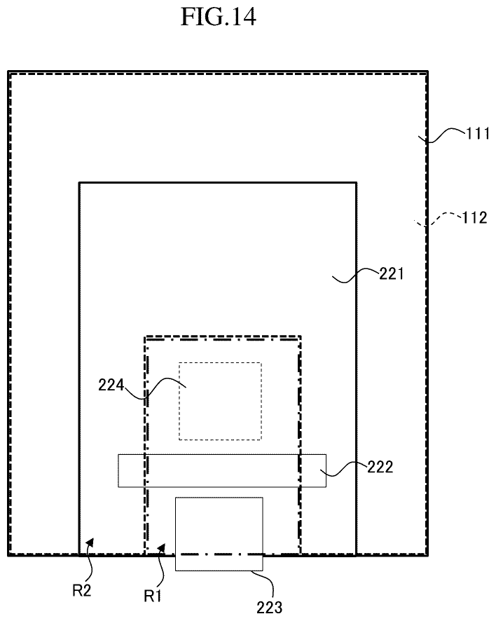

The external configuration of the module according to the second embodiment is the same as in FIG. 1. FIG. 11 is a cross-sectional view along line III-III′ of FIG. 1. FIG. 12 is a cross-sectional view along line IV-IV′ of FIG. 1. FIG. 13 is a plan view along line XIII-XIII′ of FIG. 11. FIG. 14 is a plan view along line XIV-XIV′ of FIG. 11.

As shown in FIGS. 11 and 12, the first metal layer 111 and the second metal layer 112 are stacked on the inner surface of the first face part S1. The first mounting board 210 is stacked on the first metal layer 111 The first mounting board 210 is provided so that the first metal layer 111 is in contact with the housing 100 side surface of the semiconductor chips (the controller 212 and the flash memory 213). The first metal layer 111 is stacked on the side face of the second metal layer 112 and the surface on the opposite side on the housing 100 side of the second metal layer 112.

As shown in FIG. 13, when viewed in plan in the direction indicated by the arrow on line XIII-XIII′ in FIG. 11, the inner surface of the first face part S1 is divided into a rectangular first region R1 (the region enclosed by the single-dotted line) and a second region R2 between the outer edge of the first region R1 and the outer edge of the inner surface of the first face part S1. The first region R1 includes at least the contact surface between the surface on the housing 100 side of the semiconductor chips (the controller 212 and the flash memory 213) and the first metal layer 111. In the second region R2, a stacked part of the second metal layer 112 and the first metal layer 111 is formed. This stacked part comprises the second metal layer 112 stacked on the first face part S1 and the first metal layer 111 stacked on the second metal layer 112. In this example, the stacked part is formed over (in all of) all of the second region R2, but the stacked part may be formed in a part of the second region R2.

As shown in FIGS. 11 and 12, the first metal layer 111 and the second metal layer 112 are stacked on the inner surface of the second face part S2. The second mounting board 220 is stacked on the first metal layer 111. The second mounting board 220 is provided so that the surface on the housing 100 side of the bridge IC 224 is in contact with the first metal layer 111. The first metal layer 111 is stacked on the side surface of the second metal layer 112 and the surface on the opposite side on the housing 100 side of the second metal layer 112.

As shown in FIG. 14, when viewed in plan in the direction indicated by the arrow on line XIV-XIV′ in FIG. 11, the inner surface of the second face part S2 is divided into a rectangular first region R1 (the region enclosed by the single-dotted line) and a second region R2 between the outer edge of the first region R1 and the outer edge of the inner surface of the second face part S2. The first region R1 includes at least the contact surface between the surface on the housing 100 side of the semiconductor chip (the bridge IC 224) and the first metal layer 111. In the second region R2, a stacked part of the second metal layer 112 and the first metal layer 111 is formed. This stacked part comprises the second metal layer 112 stacked on the second face part S2 and the first metal layer 111 stacked on the second metal layer 112. In this example, the stacked part is formed over all (in all) of the second region R2, but the stacked part may be formed in a part of the second region R2.

On the inner surface of the first face part S1, the module has the stacked part of the first metal layer 111 and the second metal layer 112 in the second region R2 outside the first region R1 that includes the contact surface between the housing 100 side surface of the semiconductor chip and the first metal layer 111. Further, the module has the stacked part of the first metal layer 111 and the second metal layer 112 in the second region R2 outside the first region R1 that includes the contact surface between the housing 100 side surface of the semiconductor chip and the first metal layer 111 on the inner surface of the second face part S2. The module can improve heat dissipation efficiency by having the stacked part formed in the second region R2, so that heat generated by the semiconductor chip can be dissipated efficiently to the outside without increasing the thickness of the module.

### Effect

As explained above, the module according to the second embodiment of the present invention can improve heat dissipation efficiency without increasing the thickness of the module as in the first embodiment. The module according to the second embodiment can suppress the decrease in data transfer rate due to temperature rise.

### Third Embodiment

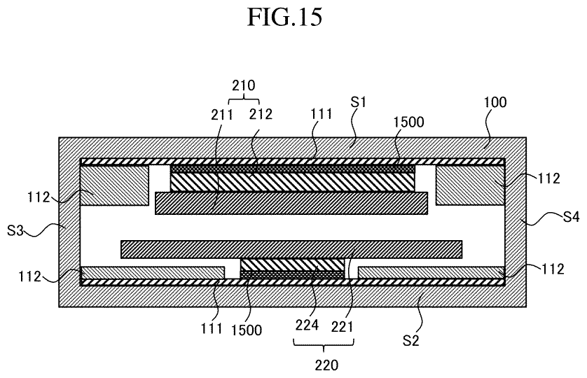

The module according to the third embodiment of the present invention will be described. The module according to the third embodiment differs from the module according to the first embodiment only in that it uses a heat-dissipating agent 1500 (see FIG. 15).

The following explanation focuses on these differences.

### Configuration

The external configuration of the module according to the third embodiment is the same as in FIG. 1. FIG. 15 is a cross-sectional view along line III-III′ of FIG. 1.

As shown in FIG. 15, a first metal layer 111 is stacked on the inner surface of the first face part S1. A first mounting board 210 and a second metal layer 112 are stacked on the first metal layer 111. The first mounting board 210 has the heat-dissipating agent 1500 formed between the housing 100 side surface of the semiconductor chips (the controller 212 and the flash memory 213) and the first metal layer 111, so that the heat-dissipating agent 1500 is in contact with the housing 100 side surface of the semiconductor chips and the heat-dissipating agent 1500 is in contact with the first metal layer 111. The surface on the housing 100 side of the semiconductor chip (the controller 212 and the flash memory 213) is in indirect contact with the first metal layer 111 through the heat-dissipating agent 1500. As the heat-dissipating agent 1500, a material that efficiently transfers heat can be used, for example, a material whose thermal conductivity is 1 (W/m-K) or more and 5 (W/m-K) or less can be used.

The first metal layer 111 is stacked on the inner surface of the second face part S2. The second mounting board 220 and the second metal layer 112 are stacked on the first metal layer 111. The second mounting board 220 has the heat-dissipating agent 1500 formed between the surface on the housing 100 side of the bridge IC 224 and the first metal layer 111, so that the heat-dissipating agent 1500 is in contact with the surface on the housing 100 side of the bridge IC 224, and the heat-dissipating agent 1500 is in contact with the first metal layer 111. The semiconductor chip (the bridge IC 224) is in indirect contact with the first metal layer 111 through the heat-dissipating agent 1500. The other configuration is the same as that of the module according to the first embodiment.

### Effect

As explained above, the module according to the third embodiment of the present invention can improve heat dissipation efficiency without increasing the thickness of the module as in the first embodiment. The module according to the third embodiment can suppress the decrease in data transfer rate due to temperature rise. Furthermore, the module according to the third embodiment can further improve the heat dissipation efficiency by providing the heat-dissipating agent 1500.

### Fourth Embodiment

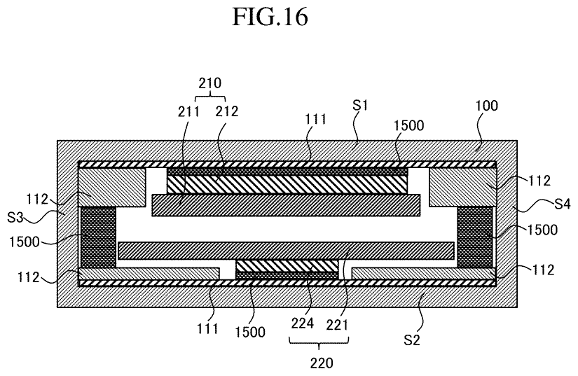

The module according to the fourth embodiment of the present invention will be described. The module according to the fourth embodiment differs from the module according to the third embodiment in the configuration and the arrangement of the heat-dissipating agent 1500 (see FIG. 16.).

The following explanation focuses on these differences.

### Configuration

The external configuration of the module according to the fourth embodiment is the same as in FIG. 1. FIG. 16 is a cross-sectional view along line III-III′ of FIG. 1.

As shown in FIG. 16, a first metal layer 111 is stacked on the inner surface of the first face part S1. A first mounting board 210 and a second metal layer 112 are stacked on the first metal layer 111. The first mounting board 210 has a heat-dissipating agent 1500 formed between the housing 100 side surface of the semiconductor chips (the controller 212 and the flash memory 213) and the first metal layer 111, so that the heat-dissipating agent 1500 is in contact with the housing 100 side surface of the semiconductor chips and the heat-dissipating agent 1500 is in contact with the first metal layer 111. The surface on the housing 100 side of the semiconductor chips (the controller 212 and the flash memory 213) is in indirect contact with the first metal layer 111 via the heat-dissipating agent 1500.

The first metal layer 111 is stacked on the inner surface of the second face part S2. The second mounting board 220 and the second metal layer 112 are stacked on the first metal layer 111. The second mounting board 220 has the heat-dissipating agent 1500 formed between the housing 100 side of the bridge IC 224 and the first metal layer 111, so that the heat-dissipating agent 1500 is in contact with the housing 100 side surface of the bridge IC 224, and the heat-dissipating agent 1500 is in contact with the first metal layer 111. The surface on the housing 100 side of the semiconductor chips (the bridge IC 224) is in indirect contact with the first metal layer 111 via the heat-dissipating agent 1500.

Furthermore, the heat-dissipating agent 1500 is provided between the second metal layer 112 on the first face part S1 side and the second metal layer 112 on the second face part S2 side so that it contacts the second metal layer 112 on the first face part S1 side and the second metal layer 112 on the second face part S2 side. In the module according to the fourth embodiment, the heat dissipation effect can be further enhanced by connecting the stacked part on the first face part S1 side and the stacked part on the second face part S2 side by means of the heat-dissipating agent 1500, thereby equalizing the housing temperature.

### Effect

As explained above, the module according to the fourth embodiment of the present invention can improve heat dissipation efficiency without increasing the thickness of the module as in the first embodiment. The module according to the fourth embodiment can suppress the decrease in data transfer rate due to temperature rise. Furthermore, the module according to the fourth embodiment can further improve the heat dissipation efficiency by connecting the stacked part on the first face part S1 side and the stacked part on the second face part S2 side by the heat-dissipating agent 1500.

### <<Variation Example>>

The present invention is not limited to the above embodiments, and various variations may be employed within the scope of the present invention. Furthermore, the above embodiments can be combined with each other as long as they do not depart from the scope of the present invention. For example, the features of the third embodiment may be applied to the second embodiment. For example, the features of the fourth embodiment may be applied to the second embodiment.

In each of the above embodiments, the module is the SSD module, but the module is not limited to the SSD module, and may be a module other than the SSD as long as it has a configuration in which the electronic component mounting board is housed in the housing 100.

What is claimed is:

1. A module comprising:
a housing with a first face part and a second face part that are opposite each other; and
an electronic component mounting board that is housed in the housing and that has a semiconductor device and a board on which the semiconductor device is mounted,
wherein,
the first metal layer formed on at least a part of an inner surface of at least one of the first face part and the second face part of the housing and a surface on a housing side of the semiconductor device are in direct or indirect contact; and
a stacked part in which the first metal layer and the second metal layer are stacked is formed on at least a part of a second region between an outer edge of a first region including a contact surface between the first metal layer and the surface on the housing side of the semiconductor device and an outer edge of the inner surface of the housing.

2. The module according to claim 1,
wherein,
the first metal layer is formed on all of the inner surface; and
the stacked part consists of a part of the first metal layer formed on the inner surface of the housing and the second metal layer formed on a part of the first metal layer.

3. The module according to claim 1,
wherein,
the first metal layer is formed on a part of the inner surface of the housing;
the second metal layer is formed on the other part of the inner surface of the housing;
the first metal layer is formed on the second metal layer; and
the stacked part consists of the second metal layer and the first metal layer formed on the second metal layer.

4. The module according to claim 1,
wherein,
the stacked part is formed on all of the second region.

5. The module according to claim 1,
wherein,
the stacked part is formed so that a side surface of the stacked part contacts the inner surface of the housing.

6. The module according to claim 4,
wherein,
an inner edge of the stacked part and an outer edge of the semiconductor device facing the inner edge of the stacked part are separated by a predetermined width.

7. The module according to claim 1,
wherein,
a first metal comprising the first metal layer and a second metal comprising the second metal layer are the same or different materials.

8. The module according to claim 1,
wherein,
the first metal layer is composed of copper; and
the second metal layer is composed of aluminum.

9. The module according to claim 1,
wherein,
a thermal conductivity of a first metal comprising the first metal layer is greater than or equal to a thermal conductivity of a second metal comprising the second metal layer.

10. The module according to claim 1,
wherein,
a heat-dissipating agent is provided between the first metal layer formed on the inner surface of the housing and a housing side surface of the semiconductor device; and
the first metal layer and the housing side surface of the semiconductor device are in indirect contact through the heat-dissipating agent.

11. The module according to claim 1,
wherein,
the housing is provided with a heat-dissipating agent between the stacked part on the inner surface of the first face part and the stacked part on the inner surface of the second face part.

12. The module according to claim 1,
wherein,
a thickness of the second metal layer is thicker than a thickness of the first metal layer.
